(19) United States
(12) Patent Application Publication
(10) Pub. No.: US 2025/0239452 A1
(43) Pub. Date: Jul. 24, 2025

(54) DIRECT NITRATION FOR BACKSIDE POWER DELIVER NETWORK ISOLATION MODULE

(71) Applicant: Applied Materials, Inc., Santa Clara, CA (US)

(72) Inventors: Prasad BHOSALE, San Jose, CA (US); Veeraraghavan S. BASKER, Schenectady, NY (US); Benjamin COLOMBEAU, Salem, MA (US); Johanes F. SWENBERG, Los Gatos, CA (US); Theresa Kramer GUARINI, San Jose, CA (US)

(21) Appl. No.: 18/947,267

(22) Filed: Nov. 14, 2024

Related U.S. Application Data
(60) Provisional application No. 63/622,881, filed on Jan. 19, 2024.

(51) Int. Cl. H01L 21/283; H01L 21/02; H01L 21/3065; H01L 29/06; H01L 29/08; H01L 29/16; H01L 29/24; H01L 29/423; H01L 29/66; H01L 29/775; H01L 29/786

(52) U.S. Cl. CPC H01L 21/283; H01L 21/02247; H10D 30/014; H10D 62/151; H01L 21/3065; H10D 30/43; H10D 30/6735; H10D 30/6757; H10D 62/121; H10D 62/80; H10D 62/83

(57) ABSTRACT

A method of backside processing of a transistor structure includes performing a substrate trench etch process to form a trench within a substrate and leave a portion of the substrate below a bottom of the trench un-etched, wherein the trench is aligned with a gate of the transistor structure, performing a nitridation process to nitride an inner surface of the trench to form a nitride layer at the inner surface, and after forming the nitride layer, performing a dielectric fill process to form a dielectric layer within the trench.

### CROSS-REFERENCE TO RELATED APPLICATIONS

This application claims priority to U.S. Provisional Application Ser. No. 63/622,881 filed Jan. 19, 2024, which is herein incorporated by reference in its entirety.

### BACKGROUND

### Field

Embodiments described herein generally relate to semiconductor device fabrication, and more particularly, to forming an isolation module for backside power delivery.

### Description of the Related Art

Traditionally, chips are constructed with transistors on a front side of a silicon wafer and all interconnects that power them and transmit their data signals built above them, i.e., to deliver power on the front side of a chip. One of the key technologies to enable scaling below 3 nm involves delivering of power on a back side of a chip. This backside power delivery eliminates the need to share interconnect resources between signals and power lines on a front side of the chip as power is moved to the back side of the chip. Backside power delivery further eliminates the need for a power delivery track from lower layer front side interconnects, leading to cost savings. Backside power delivery also allows different metal layers to be optimally fabricated, such as wider lines for an operating voltage V_{dd} and a common ground voltage Vₛₛ, and thinner lines to carry signals.

However, backside power delivery creates new challenges, such as patterning electrical contact features isolated from one another by isolation modules on a backside of a chip within tight spaces without impacting performance of transistors on a front side of the chip.

Therefore, there is a need for methods for overcoming such challenges in backside power delivery.

### SUMMARY

Embodiments of the present disclosure provide a method of backside processing of a transistor structure. The method includes performing a substrate trench etch process to form a trench within a substrate and leave a portion of the substrate below a bottom of the trench un-etched, wherein the trench is aligned with a gate of the transistor structure, performing a nitridation process to nitride an inner surface of the trench to form a nitride layer at the inner surface, and after forming the nitride layer, performing a dielectric fill process to form a dielectric layer within the trench.

Embodiments of the present disclosure also provide a method of backside processing of a transistor structure. The method includes performing a substrate trench etch process to form a trench within a substrate and leave a portion of the substrate below a bottom of the trench un-etched, wherein the trench is aligned with a gate of the transistor structure, and performing a nitridation process to nitride an inner surface of the trench to form a nitride layer.

Embodiments of the present disclosure further provide a semiconductor structure. The semiconductor structure includes a substrate having a trench formed therein, a nitride layer on an inner surface of the trench, an source/drain (S/D) epitaxial (epi) layer, and an S/D epi liner surrounding the S/D epi layer separated from the trench via the nitride layer, wherein the nitride layer has a thickness of between 3 nm and 7 nm at a bottom of the trench.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a multi-chamber processing system, according to one or more embodiments of the present disclosure.

FIG. 2 is an isometric view of a portion of a semiconductor structure that may form a gate-all-around field-effect transistor (GAA FET), according to one or more embodiments of the present structure.

FIG. 3 depicts a process flow diagram of a method of forming cell transistors in a semiconductor structure according to one embodiment.

FIGS. 4A, 4B, 4C, 4D, 4E, and 4F are cross-sectional views of a portion of a semiconductor structure corresponding to various states of the method of FIG. 3.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide methods for forming a backside power delivery structure on a backside of a chip while protecting extension regions (e.g., doped silicon (Si) or silicon germanium (SiGe)) and gate stacks (e.g., high-k dielectric, titanium nitride (TiN)) on a front side of the chip. Since patterning a silicon (Si) wafer from the backside selectively to the extension regions is not possible, nitride layers (e.g., silicon nitride (Si₃N₄)) are formed above the extension regions and the gate stacks to protect the gate stacks and the extension regions from any damage during the etching of the silicon (Si) wafer.

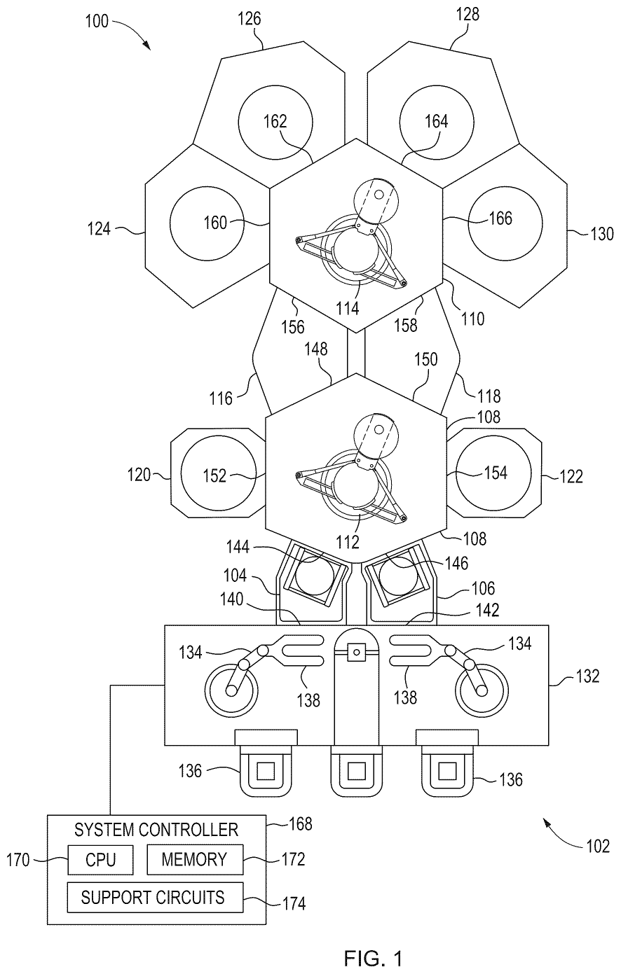

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing etch processes, the processing chamber 122 can be capable of performing cleaning processes, the processing chamber 124 can be capable of performing selective removal processes, the processing chamber 126 can be capable of performing chemical vapor deposition (CVD) deposition processes, and the processing chambers 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126 may be a W×Z™ chamber available from Applied Materials of Santa Clara, Calif. The processing chamber 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

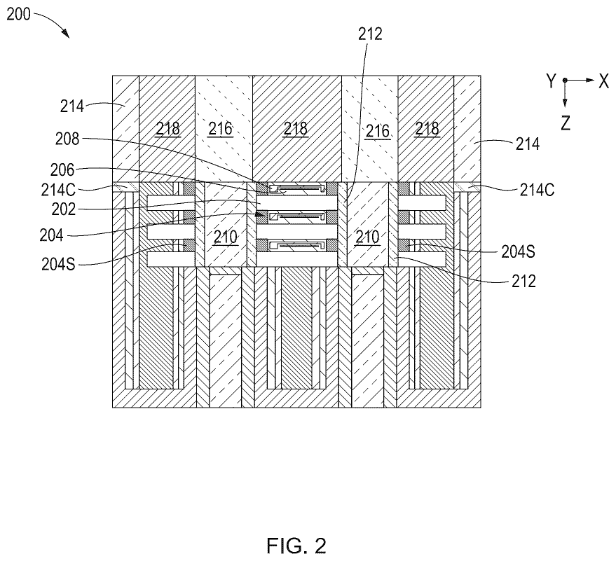

FIG. 2 is a cross-sectional view of a portion of a transistor structure 200 that may form a gate-all-around field-effect transistor (GAA FET), according to one or more embodiments of the present structure. In FIG. 2, a cut-out of the transistor structure 200 along the YZ plane including the line A-A, and a cut-out of the transistor structure 200 along the ZX plane including the line B-B are shown. The transistor structure 200 is formed on a substrate and a backside of the transistor structure 200 is shown upwards in FIG. 2.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

As shown in FIG. 2, the transistor structure 200 includes channel layers 202 and replacement-metal-gate (RMG) stacks 204. Each of the RMG stacks 204 includes a gate metal 206 and a high-k material 208.

The channel layers 202 may be formed of silicon (Si), germanium (Ge), silicon germanium (SiGe), or indium gallium zinc oxide (IGZO). Surfaces of the RMG stacks 204 may be covered by inner spacers 204S disposed on both sides of the RMG stacks 204 in the X direction. The inner spacers 204S may be formed of dielectric material, such as silicon oxide (SiO₂), silicon oxy-carbide (SiOC), silicon oxy-carbon-nitride (SiOCN), silicon boron carbon nitride (SiBCN), or silicon nitride (Si₃N₄). The gate metal 206 may be formed of titanium nitride (TiN), or titanium aluminum carbide (TiAlC), or tungsten (W). The high-k material 208 may be formed of hafnium oxides (HfO₂), hafnium zirconium oxide (HfZrO₂), or aluminum oxide (Al₂O₃).

The transistor structure 200 further includes source/drain (S/D) epitaxial (epi) layers 210 that are each surrounded by an S/D epi liners 212. The S/D epi liners 212 are electrically isolated from the RMG stacks 204 by the inner spacers 204S.

The S/D contact may be formed of tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof.

The S/D epi layer 210 may be formed of epitaxially grown silicon germanium (SiGe) with a ratio of germanium (Ge) ranging between 25% and 50%, doped with p-type dopants such as boron (B) or gallium (Ga), with a concentration of between about 10²⁰ cm⁻³ and 5×·10²¹ cm⁻³, or epitaxially grown silicon (Si), doped with n-type dopants, such as phosphorus (P), arsenic (As), or antimony (Sb), with a concentration of between about 10²⁰ cm⁻³ and 5×·10²¹ cm⁻³.

The S/D epi liner 212 may be formed of silicon (Si) or silicon germanium (SiGe) with a ratio of germanium (Ge) ranging between 0% and 15%, for example, about 10%, lightly doped with p-type dopants such as boron (B) or gallium (Ga), with a concentration of between about 1×10¹⁸ cm⁻³ and 5×10²⁰ cm⁻³, depending upon the desired conductive characteristic of the S/D epi liner 212.

The transistor structure 200 further includes shallow trench isolations (STIs) 214 formed within the substrate. The STIs 214 may be capped with an STI cap layer 214C. The STIs 214 may be formed of silicon oxide (SiO₂). The STI cap layer 214C may be formed of silicon nitride (Si₃N₄) or silicon oxynitride (SiON). The S/D epi layers 210 are each aligned with an S/D contact 216 and electrically connected to the channel layers 202 via the S/D epi liners 212. The RMG stack 204 is aligned with a backside inter-layer dielectric (ILD) 218 formed between adjacent S/D contacts 216 in the X direction.

The S/D contacts 216 may be formed of contact metal material, such as tungsten (W), cobalt (Co), ruthenium (Ru), or molybdenum (Mo).

The backside ILD 218 may be formed of silicon oxide (SiO₂), silicon oxynitride (SiON), aluminum oxide (Al₂O₃), silicon oxy-carbon-nitride (SiOCN), or any combination thereof.

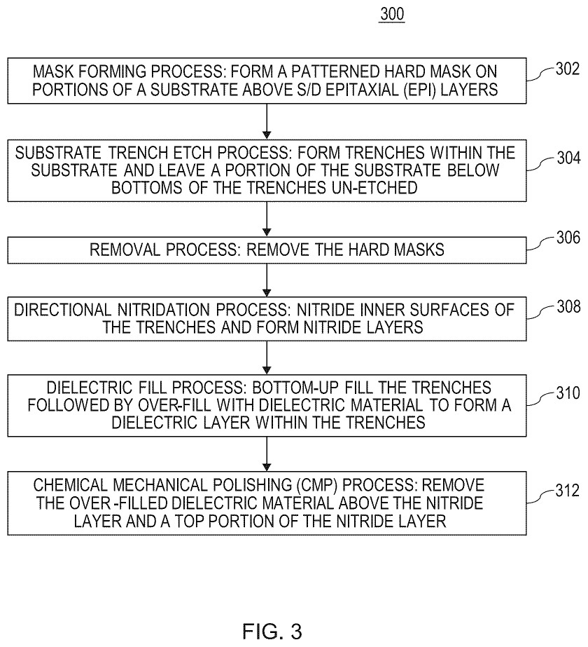

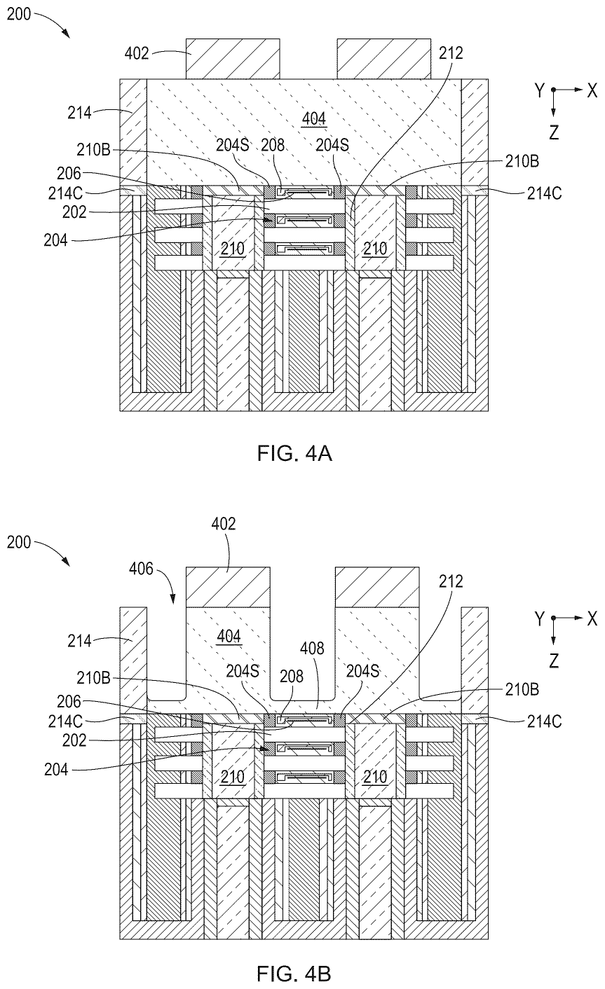

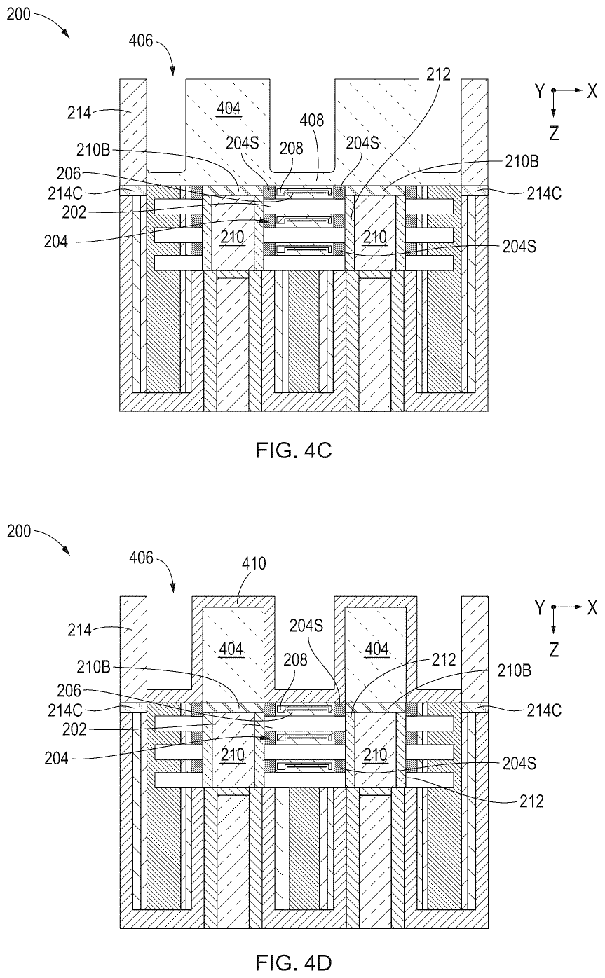

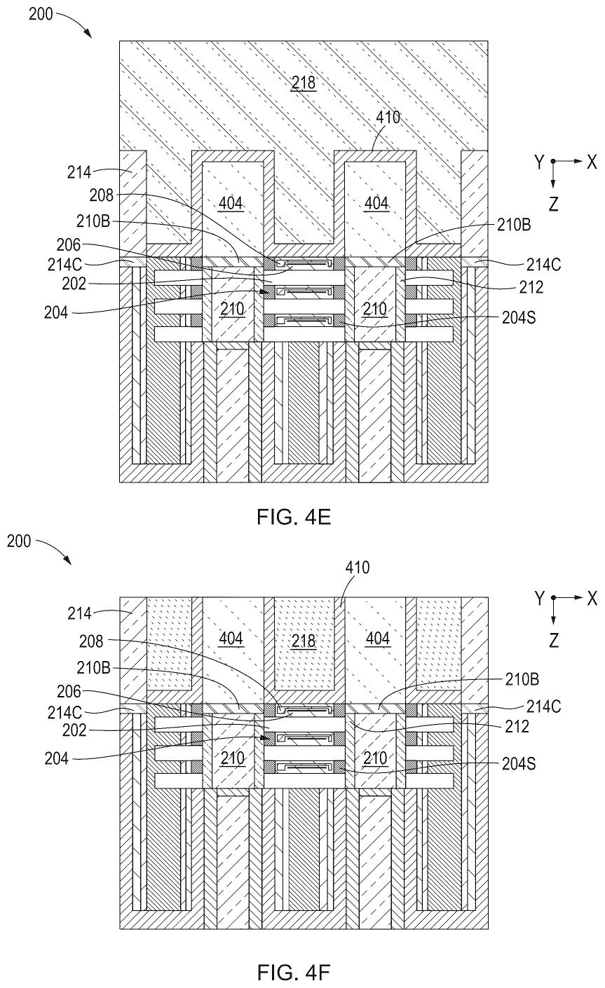

FIG. 3 depicts a process flow diagram of a method 300 of forming a semiconductor structure 400 that may be the transistor structure 200 forming a portion of a gate-all-around field-effect transistor (GAA FET), according to one or more embodiments of the present disclosure. FIGS. 4A, 4B, 4C, 4D, 4E, and 4F are cross-sectional views of a portion of the semiconductor structure 400, corresponding to various states of the method 300. A backside of the semiconductor structure 400 is shown upwards. It should be understood that FIGS. 4A, 4B, 4C, 4D, 4E, and 4F illustrate only partial schematic views of the semiconductor structure 400, and the semiconductor structure 400 may contain any number of transistor sections and additional materials having aspects as illustrated in the figures. It should also be noted that although the method illustrated in FIG. 3 is described sequentially, other process sequences that include one or more operations that have been omitted and/or added, and/or has been rearranged in another desirable order, fall within the scope of the embodiments of the disclosure provided herein.

The method 300 begins with block 302, in which a mask forming process is performed to form a patterned hard mask 402 on portions of a substrate 404 above S/D epitaxial (epi) layers 210, as shown in FIG. 4A. The hard mask 402 may be formed of silicon nitride (Si₃N₄), silicon oxynitride (SiON), or aluminum oxide (Al₂O₃). The S/D epi layers 210 may be protected by bottom nitride layers 210B while the substrate is etched from the backside of the transistor structure 200. The bottom nitride layers 210B may be formed of silicon nitride (Si₃N₄). In some embodiments, the bottom nitride layers 210 may be replaced by placeholders (not shown) formed of silicon germanium (SiGe) with a ratio of germanium (Ge) ranging between about 15% and about 50%.

In block 304, a substrate trench etch process is performed to form trenches 406 within the substrate 404 and leave a portion 408 of the substrate 404 below bottoms of the trenches 406 un-etched, as shown in FIG. 4B. Each of the trenches 406 is aligned with the RMG stacks 204 in the Z direction. The trenches 406 are each separated from an S/D epi liner 212 surrounding the S/D epi layer 210 by the un-etched portion 408. The un-etched portion 408 of the substrate 404 may have a thickness of between about 1 nm and about 12 nm, for example, about 5 nm below the bottom of the trench 406. The substrate trench etch process may include an anisotropic etch process, such as a reactive ion etch process, performed in a processing chamber, such as Centris® Sym3® etch chamber available from Applied Materials, Inc. of Santa Clara, California, or the processing chamber 120 shown in FIG. 1. The substrate trench etch process may include a wet etch process, a radical etch process, or an atomic layer etch process.

In block 306, a removal process is performed to remove the hard masks 402, as shown in FIG. 4C.

In block 308, a directional nitridation process is performed to nitride inner surfaces of the trenches 406 and form nitride layers 410, as shown in FIG. 4D. The nitride layers 410 may be formed of silicon nitride (Si₃N₄). The un-etched portion 408 of the substrate 404 is nitridated and becomes a portion of the nitride layer 410.

The directional nitridation process may be a plasma treatment process, such as a decoupled plasma nitridation (DPN) process, a decoupled plasma (DPX) process, a decoupled plasma plus (DPX+) process, or a rapid thermal nitridation (RTN) process performed in a processing chamber, such as a Radiance™ chamber, available from Applied Materials, Inc., Santa Clara, Calif. or the processing chambers 120, 122, 124, 126, 128, and 130 shown in FIG. 1. Gases that may be used in the plasma treatment process include nitrogen containing gas, such as nitrogen (N₂), ammonia (NH₃), or mixtures thereof. The directional nitridation process may be a nitrogen (N) directional implant process, or a nitrogen (N)-radical based nitridation process.

In some embodiments, prior to the directional nitridation process, a thermal anneal process may be performed to the etched inner surfaces of the trenches 406.

The metal surface recovery process may include a plasma treatment process in a continuous mode or a pulsed mode, performed in a pre-clean chamber, such as the processing chamber 122 shown in FIG. 1. In the plasma treatment process, the inner surfaces of the trenches 406 are exposed to a plasma formed from a process gas including hydrogen (H₂), or a mixture of hydrogen (H₂) and noble gas (e.g., helium (He), argon (Ar)), carbon oxide (CO), ammonia (NH₃). The plasma treatment process may be a radical-based pre-cleaning technique using a remote plasma assisted process in a continuous mode or a pulsed mode.

In block 310, a dielectric fill process is performed to bottom-up fill the trenches 406 followed by over-fill with dielectric material to form a backside ILD 218 within the trenches 406 on the substrate 404, as shown in FIG. 4E. The dielectric material may be TEOS oxide. The dielectric fill process may include a flowable CVD process, an atomic layer deposition (ALD) process, a plasma-enhanced atomic layer deposition (PE ALD) process, or a selective CVD process, performed in a processing chamber, such as a Producer® Eterna® FCVD™ or the processing chambers 126, 128, or 130 shown in FIG. 1.

In block 312, a chemical mechanical polishing (CMP) process is performed to remove the over-filled dielectric material (e.g., silicon oxide (SiO₂)) above the nitride layer 410 and a top portion of the nitride layer 410, as shown in FIG. 4F. Subsequently, an opening is etched in the substrate 404 over the backside contacts are formed above the S/D epi layer 210 and an S/D contact 216 to the S/D epi layer 210, to arrive the transistor structure 200 shown in FIG. 2.

The embodiments described herein provide methods for forming a backside power delivery structure on a backside of a chip while protecting extension regions (e.g., doped silicon (Si) or silicon germanium (SiGe)) and gate stacks (e.g., high-k dielectric, titanium nitride (TiN)) on a front side of the chip. Since patterning a silicon (Si) wafer from the backside selectively to the extension regions is not possible, nitride layers (e.g., silicon nitride (Si₃N₄)) are formed above the extension regions and the gate stacks to protect and the gate stacks and the extension regions from any damage during the etching of the silicon (Si) wafer.

While the foregoing is directed to embodiments of the present disclosure, other and further embodiments of the disclosure may be devised without departing from the basic scope thereof, and the scope thereof is determined by the claims that follow.

1. A method of backside processing of a transistor structure, comprising:
performing a substrate trench etch process to form a trench within a substrate and leave a portion of the substrate below a bottom of the trench un-etched, wherein the trench is aligned with a gate of the transistor structure;
performing a nitridation process to nitride an inner surface of the trench to form a nitride layer at the inner surface; and
after forming the nitride layer, performing a dielectric fill process to form a dielectric layer within the trench.

2. The method of claim 1, wherein:
the substrate comprises silicon (Si) and the nitride layer comprises silicon nitride (Si₃N₄), and
the transistor structure includes a source/drain (S/D) epitaxial (epi) layer and an S/D epi liner that surrounds the S/D epi layer.

3. The method of claim 2, further comprising etching an opening in the substrate over the S/D epi layer and forming an S/D contact to the S/D epi layer.

4. The method of claim 1, wherein the un-etched portion of the substrate has a thickness of between 1 nm and 12 nm.

5. The method of claim 1, wherein:
the substrate trench etch process comprises a reactive ion etch process, a wet etch process, a radical etch process, or an atomic layer etch process,
the nitridation process comprises a decoupled plasma nitridation (DPN) process, rapid thermal nitridation (RTN) process, a nitrogen (N) directional implant process, or a nitrogen (N)-radical based nitridation process, and
the dielectric fill process comprises a flowable chemical vapor deposition (CVD) process, an atomic layer deposition (ALD) process, a plasma-enhanced atomic layer deposition (PE ALD) process, or a selective CVD process.

6. The method of claim 1, wherein the dielectric layer comprises silicon nitride (Si₃N₄), silicon oxide (SiO₂), silicon oxy-carbide (SiOC), silicon oxy-carbon-nitride (SiOCN), or amorphous carbon (a-C).

7. A method of backside processing of a transistor structure, comprising:
performing a substrate trench etch process to form a trench within a substrate and leave a portion of the substrate below a bottom of the trench un-etched, wherein the trench is aligned with a gate of the transistor structure; and
performing a nitridation process to nitride an inner surface of the trench to form a nitride layer.

8. The method of claim 7, wherein:
the substrate comprises silicon (Si) and the nitride layers comprise silicon nitride (Si₃N₄), and
the transistor structure includes a source/drain (S/D) epitaxial (epi) layer and an S/D epi liner that surrounds the S/D epi layer.

9. The method of claim 8, further comprising:
after forming the nitride layer, performing a dielectric fill process to form a dielectric layer within the trench.

10. The method of claim 9, further comprising:
etching an opening in the substrate over the S/D epi layer and forming an S/D contact to the S/D epi layer.

11. The method of claim 7, wherein the un-etched portion of the substrate has a thickness of between 1 nm and 12 nm.

12. The method of claim 7, wherein:
the substrate trench etch process comprises a reactive ion etch process a wet etch process, a radical etch process, or an atomic layer etch process, and
the nitridation process comprises a decoupled plasma nitridation (DPN) process, rapid thermal nitridation (RTN) process, a nitrogen (N) directional implant process, or a nitrogen (N)-radical based nitridation process.

13. A semiconductor structure, comprising:
a substrate having a trench formed therein;
a nitride layer on an inner surface of the trench;
an source/drain (S/D) epitaxial (epi) layer; and
an S/D epi liner surrounding the S/D epi layer separated from the trench via the nitride layer,
wherein the nitride layer has a thickness of between 3 nm and 7 nm at a bottom of the trench.

14. The semiconductor structure of claim 13, wherein the substrate comprises silicon (Si) and the nitride layer comprises silicon nitride (Si₃N₄).

15. The semiconductor structure of claim 13. wherein the S/D epi layer comprises epitaxially grown silicon germanium (SiGe) with a ratio of germanium (Ge) ranging between 25% and 50%, doped with p-type dopants, or epitaxially grown silicon (Si), doped with n-type dopants.

16. The semiconductor structure of claim 13, wherein the S/D epi liner comprises silicon (Si) or silicon germanium (SiGe) with a ratio of germanium (Ge) ranging between 0% and 15%, lightly doped with p-type dopants.

17. The semiconductor structure of claim 13, further comprising:
a channel layer that is electrically connected to the S/D epi layer;
a replacement gate stack, comprising:
a gate metal; and
a high-k material;
a dielectric layer within the trench; and
a shallow trench isolation (STI) formed within the substrate.

18. The semiconductor structure of claim 17, wherein:
the channel layer comprises silicon (Si), germanium (Ge), silicon germanium (SiGe), or indium gallium zinc oxide (IGZO), and
the gate metal comprises titanium nitride (TiN), or titanium aluminum carbide (TiAlC), or tungsten (W).

19. The semiconductor structure of claim 17, wherein:
the high-k material comprises hafnium oxides (HfO₂), hafnium zirconium oxide (HfZrO₂), or aluminum oxide (Al₂O₃), and
the STI comprises silicon oxide (SiO₂).

20. The semiconductor structure of claim 17, wherein the dielectric layer comprises silicon nitride (Si₃N₄), silicon oxide (SiO₂), silicon oxy-carbide (SiOC), silicon oxy-carbon-nitride (SiOCN), or amorphous carbon (a-C).
